(19) United States
(12) Patent Application Publication
(10) Pub. No.: US 2015/0382479 A1
(43) Pub. Date: Dec. 31, 2015

(54) PRE-APPLIED CONDUCTIVE ADHESIVE FOR EMI SHIELDING

(71) Applicant: PARKER-HANNIFIN CORPORATION, Cleveland, OH (US)

(72) Inventors: Michael H. BUNYAN, Newburyport, MA (US); Peter Z. TOROK, Brockport, NY (US); George R. WATCHKO, Wakefield, MA (US); Jeffrey CZARNECKI, Newton, PA (US)

(73) Assignee: Parker-Hannifin Corporation("Parker"), Cleveland, OH (US)

(21) Appl. No.: 14/769,838

(22) PCT Filed: Mar. 13, 2014
(86) PCT No.: PCT/US14/25755

§ 371 Date: Aug. 24, 2015

Related U.S. Application Data
(60) Provisional application No. 61/768,792, filed on Feb. 25, 2013.

(51) Int. Cl. H05K 3/32; H05K 1/05

(52) U.S. Cl. CPC H05K 3/321; H05K 1/05

(57) ABSTRACT

A method for providing EMI shielding to an electronic circuit board using an electrically-conductive thermoplastic sheet containing a pre-applied electrically-conductive adhesive composition is disclosed. The adhesive composition is fluent and form-stable, and comprises a silicone adhesive, a compatible silane and electrically-conductive particles or fibers. The adhesive is conveniently pre-applied to the thermoplastic sheet and shipped to the customer for attachment to the integrated circuit board.

### BACKGROUND OF THE INVENTION

The present invention relates to a pre-applied electrically conductive adhesive system for bonding an electrically-conductive EMI shielding thermoplastic substrate to an electronic component, such as an integrated circuit board, to provide a convenient method for protecting the electronic component from the effects of EMI radiation. This is accomplished by first preparing the adhesive system, preferably in the form of a bead or pad, and pre-applying the adhesive system to an electrically-conductive EMI shielding thermoplastic substrate. The substrate is then ready for mounting onto a conforming electronic component by the end user.

Electronic components are sources of electromagnetic (EM) radiation. The electronic components, for example, transmitters, transceivers, microcontrollers, microprocessors, circuit boards, and the like, radiate a portion of the electric signals propagating through a device as EM radiation. The EM radiation generated by electronic components can be received by other devices in close proximity, resulting in electromagnetic interference (EMI).

The EM radiation generated in this way is sometimes referred to as EM noise. Higher operating frequency ranges of electronic components leads to EM noise that primarily comprises radio frequency (RF) radiation. This RF radiation is normally referred to as RF noise. As may be used herein, EM noise and RF noise are collectively referred to as EM radiation emitted from an electronic device. Moreover, EM noise and RF noise, unless otherwise stated, may be used interchangeably throughout the specification.

Many electronic devices are shielded to impede the emission of EM noise, or to prevent the device from receiving unwanted EM radiation. The shield is a physical barrier typically made of various conductive materials, for example, metal sheets, conductive plastic composites, conductive polymer sprays, metal filled epoxy pastes and the like. The shield absorbs EM radiation thereby impeding the emission of EM noise from an assembly of the electronic devices and the shield. The shield must be affixed to the shielded device in such a way as to exclude the leakage of EMI radiation, otherwise the shielding efficiency would be reduced.

Accordingly, various attachment means incorporating mechanical fasteners and/or polymeric adhesives are typically used to attach the shield to the shielded component. Polymer-based adhesive compounds are generally preferred due to cost, convenience and performance advantages. These adhesives would ideally cure at room temperature, provide a strong physical attachment for the parts, have good electrical surface conductivity for EMI shielding, and provide protection against the intrusion of moisture and dust.

Various resins and plastics have been used to prepare adhesive compositions for EMI shielding applications. Typical adhesives include polyesters, polyamides, polyacrylates, polyimides, silicones, and the like. See, for instance, U.S. Pat. No. 4,931,479; U.S. Pat. No. 5,910,524; U.S. Pat. No. 6,451,374; U.S. Pat. No. 6,942,824; and U.S. Patent Publication No. 2007/0241303 which are exemplary. These resins can be filled with electrically-conductive particles and fibers such as copper, nickel, silver, aluminum, tin or a tin alloy such as Monel. Alternatively, other conductive particles and fibers such as carbon, graphite, or a conductive polymer material may be employed.

The use of pre-applied adhesives in the electronics industry has also been suggested for various applications. U.S. Pat. No. 7,312,534 describes the use of a standard organic polymer die adhesive pre-applied to an interlayer dielectric material and a suitable substrate for making low K dielectric semiconductor chips. U.S. Pat. No. 7,456,748 is directed to RFID antennas having a standard organic polymer adhesive pre-applied to the electrical contact pads for attachment to an RFID die.

It will be appreciated that it would be desirable to develop a method for facilitating the attachment of an EMI shielding member to an electronic component by an end user or customer in a manner such that the EMI shielding of the assembly is not compromised.

### SUMMARY OF THE INVENTION

Accordingly, the present invention is directed to methods for bonding an electrically-conductive EMI shielding thermoplastic polymer substrate to an electronic component using an EMI shielding adhesive pre-applied to the thermoplastic polymer substrate. The invention is also direct to assemblies prepared using this method.

The term “pre-applied” as used herein denotes the application of the adhesive composition to the thermoplastic substrate prior to affixing the substrate to the electronic part. The substrate and adhesive combination can be supplied to an end user for the separate assembly of the components, i.e. the thermoplastic EMI shield and the electronic component. This method is intended to obviate the need for the end user to apply the adhesive to the components directly, thereby reducing the risk that the adhesive would be applied incorrectly or ineffectively.

In one embodiment, the method of the invention involves bonding an electrically-conductive thermoplastic substrate to an electronic component using a polymeric adhesive mass pre-applied to the substrate. The polymeric adhesive mass is preferably a fluent, form-stable paste formed by admixing silane, a silicone adhesive and an electrically conductive particulate filler or fibers. Preferably, the silane component is present in an amount of from about 0.5 to about 5 parts by weight of the silicone adhesive, and preferably about 1 part by weight. The adhesive compound is preferably curable by additional polymerization, rather than condensation polymerization, upon exposure of the adhesive to a thermal heating source.

In a further embodiment, an adhesive mass prepared by compounding the silane, silicone adhesive and electrically conductive filler is pre-applied to at least a portion of the contact surface of the thermoplastic substrate. The adhesive mass can physically be in the form of a form stable paste having a thixotropic consistency. The paste is formed into beads or pads, preferably beads, and dispensed onto the thermoplastic substrate as needed for the particular end use application. The end user can then affix the thermoplastic substrate/adhesive directly onto the mating surface of an electronic component, typically a printed circuit board.

In a still further embodiment, the particulate, electrically-conductive filler incorporated in the adhesive can be selected from the group consisting of particles or fibers of nickel, silver, aluminum, and alloys and mixtures thereof.

In a yet further embodiment, the substrate containing the pre-applied adhesive mass can be positioned against an exterior surface of an electronic component, compressed and heat cured to form an integrated assembly comprising the EMI shielding substrate and the electronic component. Once formed, the assembly has excellent EMI shielding, adhesion and bond strength.

The present invention, accordingly, comprises the construction, combination of elements and components, and/or the arrangement of parts and steps which are exemplified in the following detailed disclosure. The foregoing aspects and embodiments of the invention are intended to be illustrative only, and are not meant to restrict the spirit and scope of the claimed invention.

### DETAILED DESCRIPTION OF THE INVENTION

The method of the present invention is designed to affix an EMI shielding thermoplastic structure, typically a sheet, to an electronic component to form an integrated EMI-shielded assembly. An adhesive, also having EMI shielding properties, is pre-applied to the thermoplastic sheet to facilitate the use of the shielding material by the end user, and to enable the end use to conveniently form a variety of integral, composite, EMI shielded structures.

Thermoplastic sheets and structures having EMI shielding characteristics are known in the art and typically comprise a suitable thermoplastic material incorporating conductive particles or fibers, or alternatively, a coating of an electrically-conductive polymer applied to the substrate. A variety of plastic substrates can be used depending on the particular requirements of the end user. Typical plastic materials used to fabricate these sheets and structures include, by way of example and without limitation, polyethylene, polypropylene, urethane butadiene, urethane, polytetrafluoroethylene, polysulfide, and copolymer and blends of the foregoing polymers. Electrical conductivity can be provided by incorporating conductive particles or fibers in any of the above polymers during the molding operating as is generally known in the art.

The adhesive of the invention can be prepared from a silane, a silicone adhesive and electrically-conductive particles or fibers. The adhesive is electrically-conductive and has EMI shielding properties. Suitable electrically-conductive particles or fibers include, but are not limited to, nickel, silver, tin, aluminum, and alloys and mixtures thereof. The amount of conductive particles used in the adhesive can vary between wide limits. The amount (loading) and sizing of the conductive particles will determine, at least in part, the level of EMI shielding in the adhesive, the thickness of the adhesive film required, i.e. the amount of adhesive, the cure or bond time of the adhesive, the adhesive bond strength, and the degree of electrical conductivity between the shielding member and the electronic component.

The adhesive of the invention contains a silane component which is compatible with the silicone adhesive and enhances or promotes the bonding of the adhesive to the thermoplastic substrate and the electronic part. The silane is preferably addition curing with the silicone adhesive by the application of thermal energy, i.e. heating. The silane contains reactive or functional groups which react with complementary groups found on the silicone adhesive. Following the addition of the electrically conductive particles or fibers to the polymer, the resulting admixture can be compounded to form a stable mass which is suitable for further processing as described herein. The silane can be present in an amount of from about 0.5 parts by weight of adhesive to about 5.0 parts by weight of adhesive, with about one part by weight being preferred.

As indicated, the adhesive is prepared by mixing the above-identified components to form a form stable paste having a thixotropic consistency. The paste can be formed into beads or pads for convenient application to the thermoplastic substrate, with beads being the preferred form. The beads are form stable in the uncured state of the adhesive, meaning that the bead will retain its shape and not flow or run, and the particulate filler will be suspended in the adhesive without settling.

The beads are applied to the surface of the thermoplastic EMI shielding substrate, typically at the boarder or external boundary of the substrate structure, and shipped to end user customers in a “ship and stick” mode. Once received, the end user can install the shield onto the exterior surface of an electronic component, such as a printed circuit board, simply by compressing the surface of the electronic component against the surface of the substrate containing the pre-applied adhesive to provide electrical contact between the parts. The adhesive is cured by the application of heat, i.e. using a heat gun for instance. Once prepared, the assembly has board level shielding and grounding.

As it is anticipated that certain changes may be made in the present invention without departing from the precepts herein involved, it is intended that all matter contained in the foregoing description shall be interpreted as illustrative and not in a limiting sense. All references cited herein are expressly incorporated herein by reference thereto in their entirety.

What is claimed is:

1. A method of bonding an electrically-conductive EMI shielding thermoplastic substrate to the surface of an electronic component to form an assembly comprising the steps of:
preparing a polymeric adhesive mass comprising a paste of a fluent, form-stable, electrically-conductive adhesive compound to a face of the part, the compound comprising an admixture of silane, a silicone adhesive and an electrically-conductive particulate filler or fibers;
applying the adhesive mass to at least a portion of the outer surface of the thermoplastic substrate;
compressing the adhesive mass against an exterior surface of the electronic component; and
curing the compound.

2. The method of claim 1 wherein the electronic component is an integrated circuit board.

3. The method of claim 1 wherein the silane is present in an amount of from about 0.5 to about 5 parts by weight of the silicone adhesive, and preferably about 1 part by weight.

4. The method of claim 1 wherein the polymeric mass is applied in the form of beads.

5. The method of claim 1 wherein the adhesive compound is curable by addition polymerization by exposure to heat.

6. The method of claim 1 wherein the paste has a thixotropic consistency and is form stable.

7. The method of claim 1 wherein the filler is selected from the group consisting of nickel, silver, aluminum, and alloys thereof.

8. An assembly comprising an electrically-conductive EMI shielding thermoplastic substrate and a polymeric adhesive mass applied to at least a portion of the outer surface of the substrate, said polymeric adhesive mass comprising a paste of a fluent, form-stable, electrically-conductive adhesive compound further comprising an admixture of silane, a silicone adhesive and an electrically-conductive particulate filler
